(19) United States
(12) Patent Application Publication
(10) Pub. No.: US 2026/0328863 A1
(43) Pub. Date: Oct. 22, 2026

(54) ELECTRONIC DEVICE AND TESTING METHOD THEREOF

(71) Applicant: Innolux Corporation, Miaoli County (TW)

(72) Inventor: Kai-Jie You, Miaoli County (TW)

(73) Assignee: Innolux Corporation, Miaoli County (TW)

(21) Appl. No.: 19/645,319

(22) Filed: Apr. 13, 2026

(30) Foreign Application Priority Data
Apr. 22, 2025 (CN) 202510508673.6

(51) Int. Cl. G01R 31/52; H10P 74/20

(52) U.S. Cl. CPC G01R 31/52; H10P 74/207

(57) ABSTRACT

An electronic device and a testing method thereof are provided. The electronic device includes a substrate, a first data line, a first display unit group, a multiplexer, a data driver unit, a first test pad, and a test line. The substrate has an active area, a first peripheral area, and a second peripheral area. The first display unit group is disposed on the substrate and in the active area. The first data line is electrically connected to the first display unit group. The multiplexer is disposed on the substrate and in the first peripheral area, and is electrically connected to the data line. The multiplexer is electrically connected between the data line and the data driver unit. The first test pad is disposed on the substrate and in the second peripheral area. The test line is electrically connected between the first test pad and the multiplexer.

### CROSS-REFERENCE TO RELATED APPLICATION

This application claims the priority benefit of China application serial no. 202510508673.6, filed on Apr. 22, 2025. The entirety of the above-mentioned patent application is hereby incorporated by reference herein and made a part of this specification.

### BACKGROUND

### Technical Field

The disclosure relates to a device, and more particularly, to an electronic device and a testing method thereof.

### Description of Related Art

In an array test stage of a panel manufacturing process, a current testing method may only test whether an active area (AA) of the panel has a defect, but cannot test whether a fan-out wiring area has a short-circuit condition.

### SUMMARY

The disclosure provides an electronic device and a testing method thereof, which enable an effective circuit testing function during a testing stage in a manufacturing process.

According to an embodiment of the disclosure, an electronic device of the disclosure includes a substrate, a first data line, a first display unit group, a multiplexer, a data driver unit, a first test pad, and a test line. The substrate has an active area, a first peripheral area, and a second peripheral area. In a first direction, the active area is disposed between the first peripheral area and the second peripheral area. The first data line is disposed on the substrate and extends along the first direction. The first display unit group is disposed on the substrate and in the active area. The first data line is electrically connected to the first display unit group. The multiplexer is disposed on the substrate and in the first peripheral area, and is electrically connected to the first data line. The multiplexer is electrically connected between the first data line and the data driver unit. The first test pad is disposed on the substrate and in the second peripheral area. The test line is electrically connected between the first test pad and the multiplexer.

According to an embodiment of the disclosure, a testing method of the disclosure is applicable to an electronic device. The electronic device includes a first data line, a first display unit group, a multiplexer, a data driver unit, a first sub test pad, a second test pad, and a first test line. The testing method includes the following steps. A switching signal is obtained by a gate terminal of a plurality of first switching transistors of a plurality of switching units of the multiplexer from the first sub test pad through the first test line to turn on the plurality of first switching transistors. During a writing period, a writing signal is obtained by the first display unit group from the second test pad through the first data line, and a plurality of gate driver signals are received by the first display unit group to turn on a plurality of display units of the first display unit group. During a reading period, a test signal is output from the second test pad through the first data line.

Based on the above, through the electronic device and the testing method thereof of the disclosure, whether a circuit abnormality occurs may be determined through the test line and the test pad electrically connected to the multiplexer.

To make the features and advantages of the disclosure more comprehensible, several embodiments accompanied with drawings are described in detail as follows.

### BRIEF DESCRIPTION OF THE DRAWINGS

FIG. 1 is a schematic diagram of an electronic device according to an embodiment of the disclosure.

FIG. 2 is a schematic diagram of an electronic device according to an embodiment of the disclosure.

FIG. 3 is a flowchart of a testing method according to an embodiment of the disclosure.

FIG. 4 is a schematic diagram of a test circuit according to an embodiment of the disclosure.

FIG. 5 is a signal waveform diagram of a plurality of signals according to an embodiment of the disclosure.

FIG. 6 is a schematic diagram of a variation of an output voltage according to an embodiment of the disclosure.

### DESCRIPTION OF THE EMBODIMENTS

In some embodiments of the disclosure, the term “electrically connected” includes any means of direct or indirect electrical connection. In some embodiments of the disclosure, ordinal terms such as “first” and “second” used in the specification and claims are used to modify elements, and do not themselves indicate or represent any prior order of the components, nor do they indicate the sequence of one element relative to another element, or a sequence in a manufacturing method.

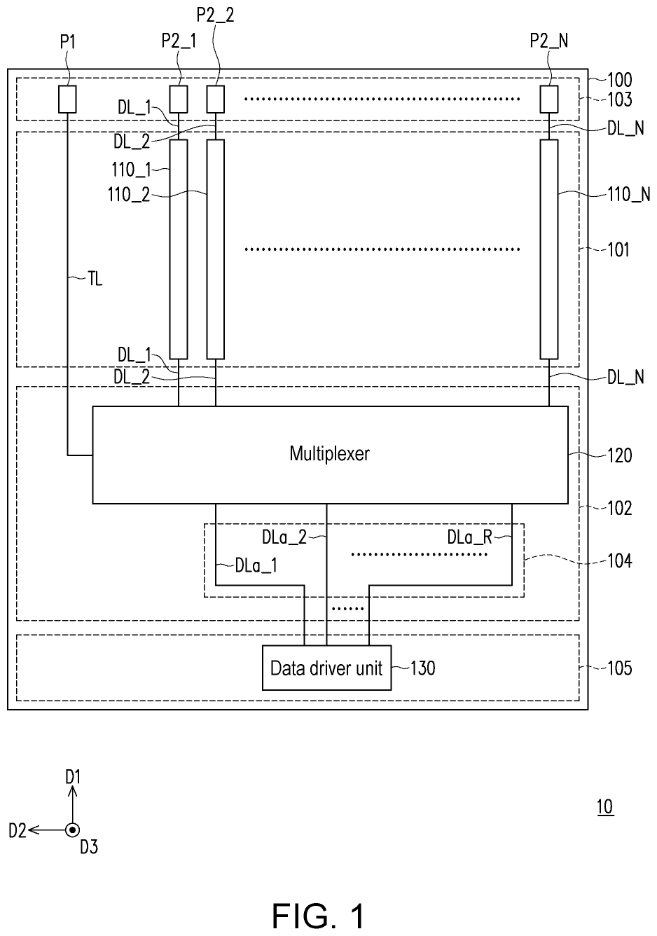

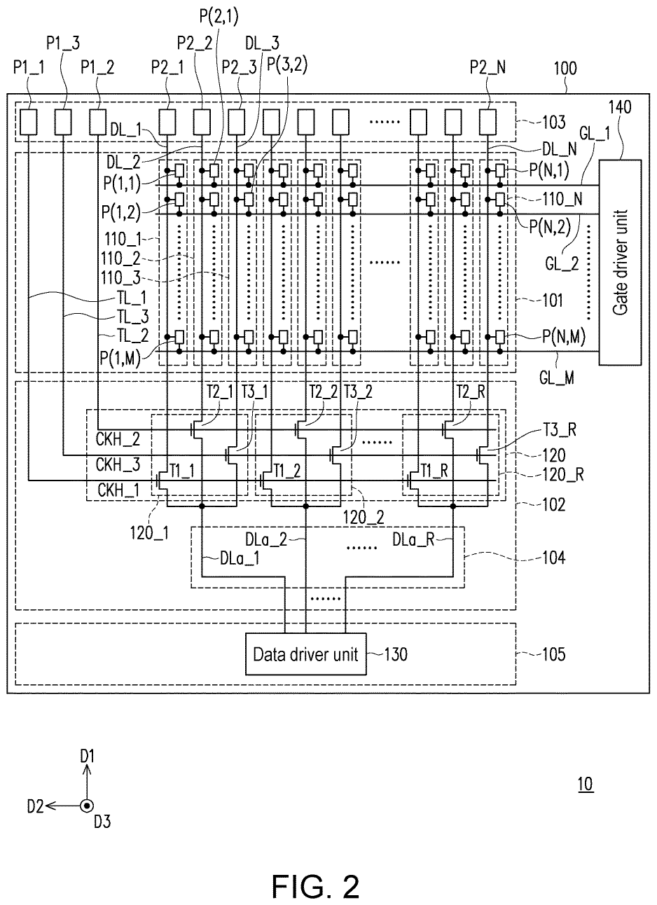

FIG. 1 is a schematic diagram of an electronic device according to an embodiment of the disclosure. Referring to FIG. 1, an electronic device 10 includes a substrate 100, a plurality of data lines DL_1~DL_N, a plurality of display unit groups 110_1~110_N, a multiplexer (MUX) 120, a data driver unit 130, a gate driver unit 140, a first test pad P1, a plurality of second test pads P2_1~P2_N, a test line TL, and a plurality of signal lines DLa_1~DLa_R, wherein N and R are positive integers, respectively. In this embodiment, the substrate 100 has an active area 101, a first peripheral area 102, a second peripheral area 103, a fan-out wiring area 104, and an outer lead bonding (OLB) area 105. In the fan-out wiring area 104, multiple wirings are disposed on the substrate 100 of a display panel and configured to distribute signals from a driving circuit or a control circuit to the inside of the substrate 100. In the disclosure, for simplicity, the fan-out wiring area 104 can refer the wirings or the signal lines in the fan-out wiring area 104. In a first direction D1, the active area 101 is disposed between the first peripheral area 102 and the second peripheral area 103. The second peripheral area 103 is disposed between the active area 101 and the outer lead bonding area 105. In this embodiment, the substrate 100 is parallel to a plane formed by the first direction D1 and a second direction D2 extending respectively, and the active area 101 is capable of emitting display light toward a third direction D3, wherein the first direction D1, the second direction D2, and the third direction D3 are perpendicular to one another. According to some embodiments, as shown in FIG. 2, a plurality of display units P(1,1)~P(N,M) may be disposed in the active area 101, and the active area 101 may be a display area. N and M are positive integers. M and N may be the same or different, and the disclosure is not limited thereto.

In this embodiment, the data lines DL_1~DL_N (N data lines) are disposed on the substrate 100 and extend along the first direction D1. The display unit groups 110_1~110_N are disposed on the substrate 100 and in the active area 101. The display unit groups 110_1~110_N are arranged along the second direction D2. The data lines DL_1~DL_N are electrically connected to the display unit groups 110_1~110_N. The display unit groups 110_1~110_N are electrically connected to the multiplexer 120 respectively through different data lines. The multiplexer 120 is disposed on the substrate 100 and in the first peripheral area 102, and is electrically connected to the data lines DL_1~DL_N. The data lines DL_1~DL_N are electrically connected between the display unit groups 110_1~110_N and the multiplexer 120. The multiplexer 120 is electrically connected between the data lines DL_1~DL_N and the data driver unit 130. The first test pad P1 is disposed on the substrate 100 and in the second peripheral area 103. The test line TL is electrically connected between the first test pad P1 and the multiplexer 120. The second test pads P2_1~P2_N are disposed on the substrate 100 and in the second peripheral area 103, and are electrically connected to the data lines DL_1~DL_N. The first test pad P1 and the second test pads P2_1~P2_N are arranged along the second direction D2.

The fan-out wiring area 104 is disposed between the multiplexer 120 and the data driver unit 130. The signal lines DLa_1~DLa_R are disposed on the substrate 100 and in the fan-out wiring area 104. The data driver unit 130 is disposed on the substrate 100 and in the outer lead bonding area 105. The multiplexer 120 is electrically connected to the data driver unit 130 through the signal lines DLa_1~DLa_R. The signal lines DLa_1~DLa_R are electrically connected between the multiplexer 120 and the data driver unit 130. According to other embodiments, although not shown, the data driver unit 130 may not be disposed on the substrate 100, but outside the substrate 100.

The electronic device 10 may include, for example, electronic components such as passive components and active components, for example, capacitors, resistors, inductors, diodes, transistors, and so on. The display panel of the display device may include, for example, liquid crystals, light-emitting diodes, quantum dots (QD), fluorescence, phosphor, other suitable materials, or a combination of the above materials, but is not limited thereto. The light-emitting diodes may include, for example, organic light-emitting diodes (OLED), mini light-emitting diodes (mini LED), micro light-emitting diodes (micro LED), or quantum dot light-emitting diodes (QLED or QDLED).

In this embodiment, the substrate 100 may be a rigid substrate or a flexible substrate. The material of the substrate 100 may include, for example, metal, plastic, glass, quartz, sapphire, ceramic, carbon fiber, or combination thereof.

In this embodiment, each of the display unit groups 110_1~110_N includes a plurality of display units. The plurality of display units of each of the display unit groups 110_1~110_N is electrically connected to the same data line. For example, as shown in FIG. 1, the plurality of display units of the display unit group 110_1 may be electrically connected to the data line DL1. The data driver unit 130 may be a display driver and includes a related display driver circuit.

FIG. 2 is a schematic diagram of an electronic device according to an embodiment of the disclosure. Referring to FIG. 2, the electronic device 10 may implement a circuit configuration as shown in FIG. 2. One display unit group may include a plurality of (M) display units. For example, the display unit group 110_1 may include a plurality of display units P(1,1)~P(1,M). The display unit P(x,y) indicates the xth display unit along the second direction D2 and the yth display unit along the first direction D1. For example, the display unit (3,2) indicates the 3rd display unit along the second direction D2 and the 2nd display unit along the first direction D1.

Each of the display units P(1,1)~P(N,M) may include a pixel transistor and a storage capacitor, wherein a gate of the pixel transistor may be electrically connected to a corresponding gate line. The display units P(1,1)~P(N,M) may be electrically connected to the gate driver unit 140 through a plurality of gate lines GL_1~GL_M (M gate lines). The gate driver unit 140 and the gate lines GL_1~GL_M are disposed on the substrate 100. The gate lines GL_1~GL_M extend along the second direction D2. As shown in FIG. 2, among the display units P(1,1)~P(N,M), display units in different rows are electrically connected to different gate lines. For example, the display units P(1,1), P(2,1)~P(N,1) arranged along the second direction D2 may be electrically connected to the gate driver unit 140 through the gate line GL_1. The display units P(1,2), P(2,2)~P(N,2) arranged along the second direction D2 may be electrically connected to the gate driver unit 140 through the gate line GL_2. According to some embodiments, the gate driver unit 140 may be disposed on the substrate 100, as shown in FIG. 2. According to some embodiments, the gate driver unit 140 may not be disposed on the substrate 100, but outside the substrate 100.

As shown in FIG. 2, the multiplexer 120 is electrically connected to the data driver unit 130 through the signal lines DLa_1~DLa_M in the fan-out wiring area 104. The multiplexer 120 may include a plurality of switching units 120_1~120_R, wherein R is a positive integer. The switching units 120_1~120_R are electrically connected to different data lines, respectively. The switching units 120_1~120_R are electrically connected between the data lines DL_1~DL_N and the data driver unit 130. The switching units 120_1~120_R include a plurality of first switching transistors T1_1~T1_R, a plurality of second switching transistors T2_1~T2_R, and a plurality of third switching transistors T3_1~T3_R. Each of the switching units 120_1~120_R includes one first switching transistor, one second switching transistor, and one third switching transistor. For example, the switching unit 120_1 includes the first switching transistor T1_1, the second switching transistor T2_1, and the third switching transistor T3_1. For convenience of explanation, the above switching transistors may be N-type transistors (as shown), but the disclosure is not limited thereto. In an embodiment, the above switching transistors may also be P-type transistors.

As shown in FIG. 2, the switching units 120_1~120_R are electrically connected between the data lines DL_1~DL_N and the data driver unit 130. First terminals of the first switching transistors T1_1~T1_R, the second switching transistors T2_1~T2_R, and the third switching transistors T3_1~T3_R are respectively electrically connected to different data lines DL_1~DL_N.

As shown in FIG. 2, the switching units 120_1~120_R are electrically connected to the data driver unit 130 through different signal lines. A second terminal of each of the first switching transistor, the second switching transistor, and the third switching transistor of each of the switching units 120_1~120_R is electrically connected to the data driver unit 130 through the same signal line. For example, the second terminals of the first switching transistor T1_1, the second switching transistor T2_1, and the third switching transistor T3_1 of the switching unit 120_1 are electrically connected to the data driver unit 130 through the signal line DLa_1.

The test line TL in FIG. 1 may include a plurality of test lines, and the test pad in FIG. 1 may include a plurality of sub test pads. As shown in FIG. 2, a gate terminal of each of the first switching transistors T1_1~T1_R of the switching units 120_1~120_R is electrically connected to a first sub test pad P1_1 through a first test line TL_1. A gate terminal of each of the second switching transistors T2_1~T2_R of the switching units 120_1~120_R is electrically connected to a second sub test pad P1_2 through a second test line TL_2. A gate terminal of each of the third switching transistors T3_1~T3_R of the switching units 120_1~120_R is electrically connected to a third test pad P1_3 through a third test line TL_3.

As shown in FIG. 2, first terminals of the first switching transistors T1_1~T1_R, the second switching transistors T2_1~T2_R, and the third switching transistors T3_1~T3_R are respectively electrically connected to different display unit groups 110_1~110_N through the data lines DL_1~DL_N. For example, a first terminal of the first switching transistor T1_1 is electrically connected to the data line DL_1, and electrically connected to the display unit group 110_1 through the data line DL_1. A first terminal of the second switching transistor T1_2 is electrically connected to the data line DL_2, and electrically connected to the display unit group 110_2 through the data line DL_2.

As shown in FIG. 2, when the electronic device 10 operates in a display mode, the data driver unit 130 may provide different data signals to the switching units 120_1~120_R through the signal lines DLa_1~DLa_R. For example, the data driver unit 130 may provide a data signal to the first switching transistor T1_1, the second switching transistor T2_1, and the third switching transistor T3_1 through the signal line DLa_1.

The first switching transistors T1_1~T1_R, the second switching transistors T2_1~T2_R, and the third switching transistors T3_1~T3_R may be turned on in a time-division manner according to different control signals, to provide corresponding data signals to the display unit groups 110_1~110_N at different times through the data lines DL_1~DL_N. For example, in a time period, the first switching transistors T1_1~T1_R may be operated in an on state, and the second switching transistors T2_1~T2_R and the third switching transistors T3_1~T3_R may be operated in an off state. Therefore, the first switching transistors T1_1~T1_R may respectively provide the data signals provided by the signal lines DLa_1~DLa_R to the display unit groups 110_1, 110_4, and 110_(N−2). Next, in a next time period, the second switching transistors T2_1~T2_R may be operated in an on state, and the first switching transistors T1_1~T1_R and the third switching transistors T3_1~T3_R may be operated in an off state. Therefore, the second switching transistors T2_1~T2_R may respectively provide the data signals provided by the signal lines DLa_1~DLa_R to the display unit groups 110_2, 110_5, and 110_(N−1). Next, the third switching transistors T3_1~T3_R may be operated in an on state, and the first switching transistors T1_1~T1_R and the second switching transistors T2_1~T2_R may be operated in an off state. Therefore, the third switching transistors T3_1~T3_R may respectively provide the data signals provided by the signal lines DLa_1~DLa_R to the display unit groups 110_3, 110_6, and 110_N.

According to some embodiments, as shown in FIG. 2, a first conductive layer (not shown) may be patterned to form a plurality of gate lines GL_1~GL_M, and a second conductive layer (not shown) may be patterned to form a plurality of data lines DL_1~DL_N. Each of the display units P(1,1)~P(N,M) may include a pixel transistor (not shown) and a pixel electrode (not shown). The pixel electrode may be a third conductive layer (not shown). The first conductive layer may be disposed on the substrate 100, the second conductive layer may be disposed on the first conductive layer, and the third conductive layer may be disposed on the second conductive layer. The first conductive layer is disposed between the substrate 100 and the second conductive layer, an insulating layer is disposed between the first conductive layer and the second conductive layer, and another insulating layer is disposed between the second conductive layer and the third conductive layer.

The pixel transistor in the display unit may be electrically connected to the corresponding gate line and data line. Specifically, taking the display unit P(1,1) for example, the gate line GL_1 may be electrically connected to a gate of the pixel transistor, and the data line DL_1 may be electrically connected to a source of the pixel transistor. The pixel electrode may be electrically connected to a drain of the pixel transistor.

According to some embodiments, the first test pad P1 may be any conductive layer on the substrate 100 or a combination of any conductive layers. For example, the first test pad P1 may include the first conductive layer. For example, the first test pad P1 may include the second conductive layer and the third conductive layer. According to some embodiments, the first test pad P1 may be any conductive layer on the substrate 100 or a combination of any conductive layers. The second test pad P2_1 may be any conductive layer on the substrate 100 or a combination of any conductive layers. The first test pad P1 and the second test pad P2_1 may include the same layer or different layers. The first test pad P1 and the test line TL1 may include the same layer or different layers. This way, when fabricating the pixel transistors, the gate lines, and the data lines on the array substrate, the first test pad P1, the second test pad P2, and/or the test line TL1 may also be fabricated at the same time, so as to simplify the process.

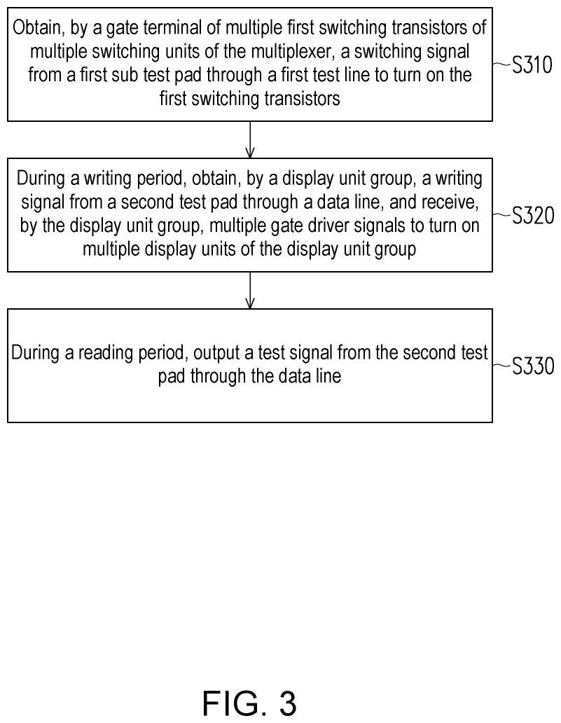

FIG. 3 is a flowchart of a testing method according to an embodiment of the disclosure. Referring to FIGS. 2 and 3, in this embodiment, when the electronic device 10 operates in a testing mode, the electronic device 10 may perform the following steps S310~S330. The following description takes testing of the display unit group 110_1 as an example. In step S310, a switching signal CKH_1 is obtained by gate terminals of the first switching transistors T1_1~T1_R of the switching units 120_1~120_R of the multiplexer 120 from the first sub test pad P1_1 through the first test line TL_1, to turn on the first switching transistors T1_1~T1_R. In step S320, during a writing period, the display unit group 110_1 obtains a writing signal from the second test pad P2_1 through the data line DL_1, and the display unit group 110_1 may receive gate driver signals through the gate lines GL_1~GL_M to turn on the plurality of display units P(1,1)~P(1,M) in the display unit group 110_1. In this regard, the writing signal may charge the plurality of storage capacitors in the display units P(1,1)~P(1,M) of the display unit group 110_1. In step S330, during a reading period, the electronic device 10 may output a test signal from the second test pad P2_1 through the data line DL_1 to the test circuit.

In this regard, the test circuit may determine whether a short-circuit condition has occurred between the signal line DLa_1 in the fan-out wiring area 104 and at least one of the other signal lines DLa_2~DLa_R according to the test signal output from the second test pad P2_1.

As shown in FIG. 2, the arrays formed by the display units P(1,1)~P(N,M) are disposed on the substrate 100. Therefore, the substrate 100 and the display units P(1,1)~P(N,M) in combination may form an array substrate. Specifically, as shown in FIGS. 1 and 2, the array substrate may include the substrate 100, the display units P(1,1)~P(N,M), the plurality of data lines DL_1~DL_N, the plurality of gate lines GL_1~GL_M, and the multiplexer 120. The display units P(1,1)~P(N,M), the plurality of data lines DL_1~DL_N, the plurality of gate lines GL_1~GL_M, and the multiplexer 120 are disposed on the substrate 100. According to some embodiments, the test line TL may be disposed on the substrate 100. The connection relationships among the above elements may be seen in the foregoing and will not be repeated here. After performing the above test, the array substrate may be combined with a counter substrate (not shown), and a display medium layer may be disposed between the array substrate and the counter substrate to form a display panel. For example, the counter substrate may be a color filter substrate, and the display medium layer may be a liquid crystal layer.

This way, according to some embodiments, by the arrangement of test pads in the array substrate of the disclosure, it is possible to detect whether the fan-out wiring area is short-circuited before the array substrate is combined with the counter substrate. That is, it is possible to detect whether the fan-out wiring area is short-circuited during the testing stage of the array substrate. In the prior art, only whether the active area of the panel has defects may be tested, but whether the fan-out wiring area is short-circuited cannot be tested. In the prior art, the fan-out wiring area is detected at the stage of the display panel. Compared with the prior art, the disclosure allows detection to be performed earlier at the testing stage of the array substrate. Therefore, a short-circuit condition may be repaired at the stage of the array substrate, and waste of materials for the counter substrate and the display medium layer in the subsequent process may be avoided.

Taking testing of the display unit group 110_2 for example, gate terminals of the second switching transistors T2_1~T2_R of the switching units 120_1~120_R of the multiplexer 120 obtain a switching signal CKH_2 from the second sub test pad P1_2 through the second test line TL_2 to turn on the gate terminals of the second switching transistors T2_1~T2_R. During a writing period, the display unit group 110_2 obtains a writing signal from the second test pad P2_2 through the data line DL_2, and the display unit group 110_2 may receive gate driver signals through the gate lines GL_1~GL_M to turn on the plurality of display units P(2,1)~P(2,M) in the display unit group 110_2. In this regard, the writing signal may charge the plurality of storage capacitors in the display units P(2,1)~P(2,M) of the display unit group 110_2. During a reading period, the electronic device 10 may output a test signal from the second test pad P2_2 through the data line DL_2 to the test circuit.

Similarly, during a writing period, the display unit group 110_3 obtains a writing signal from the second test pad P2_3 through the data line DL_3. During a reading period, the electronic device 10 may output a test signal from the second test pad P2_3 through the data line DL_3 to the test circuit.

In addition, the specific operation manner of the above-mentioned test circuit will be further described by the following embodiments.

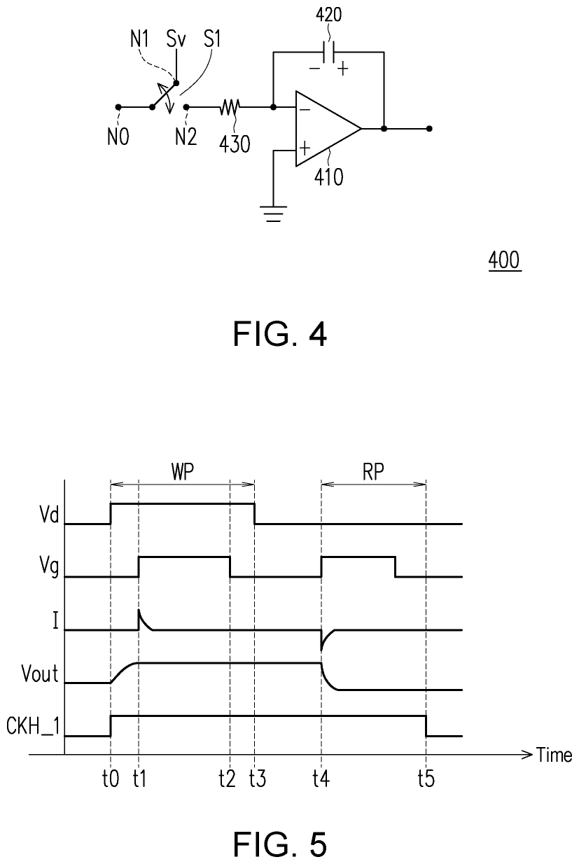

FIG. 4 is a schematic diagram of a test circuit according to an embodiment of the disclosure. Referring to FIG. 4, in this embodiment, the above-mentioned test circuit may implement a test circuit 400 as shown in FIG. 4, but the disclosure is not limited thereto. In this embodiment, the test circuit 400 includes a comparator 410, a capacitor 420, a resistor 430, and a switch S1. The capacitor 420 is electrically connected between an inverting input terminal and an output terminal of the comparator 410. A non-inverting input terminal of the comparator 410 is grounded. The resistor 430 is electrically connected between the inverting input terminal of the comparator 410 and a node N2. One end of the switch S1 is electrically connected to a circuit node NO. The other end of the switch S1 may be switched to be electrically connected to a circuit node N1 or the circuit node N2. The circuit node N1 may provide a writing signal Sv. The test circuit 400 may be electrically connected to one of the second test pads P2_1~P2_N through the circuit node NO.

FIG. 5 is a signal waveform diagram of a plurality of signals according to an embodiment of the disclosure. Referring to FIGS. 2 to 5, taking testing of the display unit group 110_1 for example, during a period from time t0 to time t5, the multiplexer 120 obtains a switching signal CKH_1 from the first sub test pad P1_1 through the first test line TL_1 to turn on the first switching transistors T1_1~T1_R. During a writing period WP from time t0 to time t3, the switch S1 of the test circuit 400 is switched to be electrically connected between the node NO and the node N1. Therefore, the test circuit 400 may provide the switching signal CKH_1 to the first sub test pad P1_1, and provide the writing signal Sv to the second test pad P2_1. The test circuit 400 may enable the comparator 410 and cause the output voltage at an output terminal of the comparator 410 to equal a reference voltage. In this regard, as shown in the following Formula (1), an amount of electric charge stored in the capacitor 420 may be equal to the reference voltage multiplied by a capacitance value of the capacitor 420. In the following Formula (1), the symbol “Qcint” may represent the amount of electric charge stored in the capacitor 420 during the writing period WP. The symbol “Vref” may represent the reference voltage. The symbol “Cint” may represent the capacitance value of the capacitor 420.

Qcint=Vref×Cint. Formula (1)

In addition, during a period from time t1 to time t2, the display unit group 110_1 may further receive gate driver signals through the gate lines GL_1~GL_M to turn on the plurality of display units P(1,1)~P(1,M) in the display unit group 110_1. In this regard, a voltage Vg of the gate driver signal may switch from a low level to a high level during the period from time t1 to time t2 to turn on the plurality of pixel transistors of the display units P(1,1)~P(1,M) in the display unit group 110_1. Therefore, at time t1, a current I on the data line DL_2 generates a positive current pulse. The writing signal Sv may charge the plurality of storage capacitors in the display units P(1,1)~P(1,M) of the display unit group 110_1. In this regard, as shown in the following Formula (2), an amount of electric charge stored in the plurality of storage capacitors of the display units P(1,1)~P(1,M) may be equal to a voltage of the writing signal Sv multiplied by a total capacitance value of the display unit group 110_1. In the following Formula (2), the symbol “Qcs” may represent the amount of electric charge stored in the plurality of storage capacitors of the display unit group 110_1. The symbol “Vd” may represent the voltage of the writing signal Sv. The symbol “Cst” may represent an equivalent capacitance value of the display unit group 110_1.

Qcs=Vd×Cst. Formula (2)

Therefore, as shown in FIG. 5, an output voltage Vout at an output terminal of the comparator 410 may rise to a high voltage (i.e., equal to the reference voltage Vref) during the period from time t0 to time t4.

Next, during a reading period RP from time t4 to time t5, the switch S1 of the test circuit 400 is switched to be electrically connected between the node NO and the node N2. In addition, at time t4, the display unit group 110_1 may receive gate driver signals through the gate lines GL_1~GL_M to turn on the display units P(1,1)~P(1,M) in the display unit group 110_1. In this regard, a voltage Vg of the gate driver signal may switch from a low voltage to a high voltage at time t4 to turn on the plurality of pixel transistors of the display units P(1,1)~P(1,M) in the display unit group 110_1. This way, an amount of electric charge stored in the plurality of storage capacitors of the display units P(1,1)~P(1,M) may form a test current and be output to the second test pad P2_1 through the data line DL_1. Therefore, during the reading period RP, the test circuit 400 may read an output voltage Vout from the second test pad P2_1 as a test signal.

In this regard, by conversion using the above Formulas (1) and (2), as shown in the following Formula (3), an amount of electric charge stored in the capacitor 420 may be affected by the test current provided by the second test pad P2_1, and be changed to a result of subtracting the amount of electric charge stored in the plurality of storage capacitors of the display units P(1,1)~P(1,M) in the display unit group 110_1 from the previously stored amount of electric charge in the capacitor 420. In the following Formula (3), the symbol “Qcint′” may represent the amount of electric charge stored in the capacitor 420 during the reading period RP. In addition, during the reading period RP, an output voltage Vout at the output terminal of the comparator 410 may be as shown in the following Formula (4).

Qcint′=Vref×Cint−Vd×Cst. Formula (3)

$$Vout = Vref - ( Vd \times \frac{Cst}{Cint} ) \qquad Formula ( 4 )$$

Therefore, as shown in FIG. 5, the output voltage Vout at the output terminal of the comparator 410 may drop during the period from time t4 to time t5.

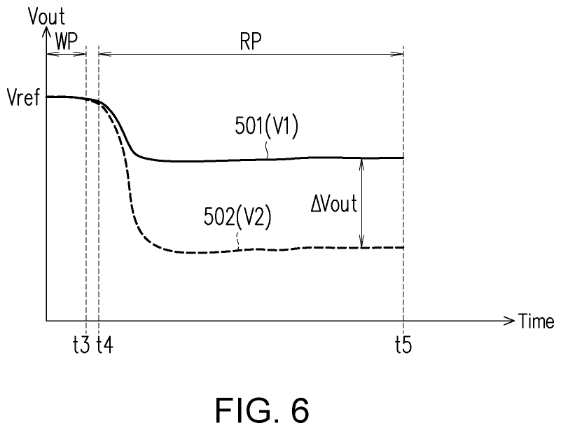

FIG. 6 is a schematic diagram of a variation of an output voltage according to an embodiment of the disclosure. Referring to FIGS. 2 to 6, continuing the above embodiment, the test circuit 400 may detect whether at least one of the multiplexer 120 and the fan-out wiring area 104 has a short-circuit condition by a voltage variation of the output voltage Vout. As shown in FIG. 6, before time t3, the output voltage Vout is equal to the reference voltage Vref. During the reading period RP from time t4 to time t5, a voltage variation of the output voltage Vout occurs.

In this regard, when no circuit abnormality occurs in the multiplexer 120 and the fan-out wiring area 104, the output voltage Vout will, as shown by curve 501, drop from the reference voltage Vref to a voltage V1 (normal voltage). Conversely, when a short-circuit condition occurs due to too small a distance between a metal wiring of the signal line DLa_1 in the fan-out wiring area 104 of the substrate 100 and other signal lines DLa_2~DLa_R, or a connection caused by a process error, since the plurality of storage capacitors of the display units P(1,1)~P(1,M) of the display unit group 110_1 will be connected in series with storage capacitors of other display unit groups through the signal line DLa_1 and at least one of the other signal lines short-circuited therewith, the equivalent capacitance value Cst will increase, as shown in the above Formula (4). This way, the output voltage Vout will, as shown by curve 502, drop from the reference voltage Vref to a lower voltage V2 (abnormal voltage).

Accordingly, the test circuit 400 may determine, for example, whether a voltage difference ΔVout between the voltage V2 and the voltage V1 exceeds a threshold, so as to effectively determine whether a short-circuit condition occurs between the signal line DLa_1 and other signal lines DLa_2~DLa_R in the fan-out wiring area 104.

In summary, the electronic device and the testing method thereof of the disclosure may, during a testing stage of an array substrate in a panel manufacturing process, effectively determine whether a short-circuit condition occurs in a wiring of the fan-out wiring area by a test line and a test pad electrically connected to the multiplexer.

Finally, it should be noted that the above embodiments are only used to illustrate the technical solutions of the disclosure and are not intended to limit the disclosure. Although the disclosure has been described in detail with reference to the foregoing embodiments, those skilled in the art should understand that modifications may still be made to the technical solutions described in the foregoing embodiments, or some or all of the technical features may be replaced with equivalents. These modifications or replacements do not cause the essence of the corresponding technical solutions to deviate from the scope of the technical solutions in the embodiments of the disclosure.

What is claimed is:

1. An electronic device, comprising:
a substrate, having an active area, a first peripheral area, and a second peripheral area, wherein in a first direction, the active area is disposed between the first peripheral area and the second peripheral area;
a first data line, disposed on the substrate and extending along the first direction;
a first display unit group, disposed on the substrate and in the active area, wherein the first data line is electrically connected to the first display unit group;
a multiplexer, disposed on the substrate and in the first peripheral area, and electrically connected to the first data line;
a data driver unit, wherein the multiplexer is electrically connected between the first data line and the data driver unit;
a first test pad, disposed on the substrate and in the second peripheral area; and
a test line, electrically connected between the first test pad and the multiplexer.

2. The electronic device according to claim 1, further comprising:
a second test pad, disposed on the substrate and in the second peripheral area, and electrically connected to the first data line.

3. The electronic device according to claim 2, further comprising:
a test circuit,
wherein during a testing stage, the first test pad and the second test pad are electrically connected to the test circuit,
the first test pad is configured to obtain a switching signal from the test circuit, and
the second test pad is configured to obtain a writing signal from the test circuit, and the second test pad is further configured to output a test signal to the test circuit.

4. The electronic device according to claim 3, wherein the test circuit comprises:
a comparator;
a capacitor, electrically connected between an inverting input terminal and an output terminal of the comparator;
a resistor, wherein a first terminal of the resistor is electrically connected to the inverting input terminal of the comparator; and
a switch, wherein a first terminal of the switch is electrically connected to a first circuit node of the test circuit, and a second terminal of the switch is switched to be electrically connected to a second circuit node and a third circuit node of the test circuit,
wherein the second circuit node is configured to provide the writing signal, and the third circuit node is electrically connected to a second terminal of the resistor.

5. The electronic device according to claim 1, further comprising:
a second data line,
wherein the multiplexer comprises:
a plurality of switching units, electrically connected to the data driver unit,
wherein each of the plurality of switching units comprises a first switching transistor and a second switching transistor,
the plurality of switching units comprises a first switching unit, and
a first terminal of the first switching transistor of the first switching unit is electrically connected to the first data line, and a first terminal of the second switching transistor of the first switching unit is electrically connected to the second data line.

6. The electronic device according to claim 5, wherein the first test pad comprises a first sub test pad and a second sub test pad,
the test line comprises a first test line and a second test line, the first test line is electrically connected to the first sub test pad, the second test line is electrically connected to the second sub test pad, and
a gate terminal of the first switching transistor of each of the plurality of switching units is electrically connected to the first test line, and a gate terminal of the second switching transistor of each of the plurality of switching units is electrically connected to the second test line.

7. The electronic device according to claim 5, further comprising:
a second display unit group, disposed on the substrate and in the active area, wherein the second data line is electrically connected between the second display unit group and the multiplexer.

8. A testing method of an electronic device, wherein the electronic device comprises a first data line, a first display unit group, a multiplexer, a data driver unit, a first sub test pad, a second test pad, and a first test line, the first data line is electrically connected to the first display unit group, the multiplexer comprises a first switching transistor and is electrically connected between the first data line and the data driver unit, the first test line is electrically connected between the first test pad and the multiplexer, and the second test pad is electrically connected to the first data line, wherein the testing method comprising:
obtaining, by a gate terminal of the first switching transistor of the multiplexer, a switching signal from the first sub test pad through the first test line to turn on the first switching transistor;
during a writing period, obtaining a writing signal by the first display unit group from the second test pad through the first data line, and receiving a plurality of gate driver signals by the first display unit group to turn on a plurality of display units of the first display unit group; and
during a reading period, outputting a test signal from the second test pad through the first data line.
